(19) United States
(12) Patent Application Publication
(10) Pub. No.: US 2026/0068620 A1
(43) Pub. Date: Mar. 5, 2026

(54) SEMICONDUCTOR INTERCONNECTION STRUCTURE AND METHODS OF FORMING THE SAME

(71) Applicant: TAIWAN SEMICONDUCTOR MANUFACTURING COMPANY, LTD., Hsinchu (TW)

(72) Inventors: Chih-Hao CHEN, Hsinchu (TW); Sheng-Yuan CHANG, Taitung (TW); Yi-Nien SU, Hsinchu (TW); Huan-Just LIN, Yilan (TW)

(21) Appl. No.: 18/816,485

(22) Filed: Aug. 27, 2024

(51) Int. Cl. H01L 23/535; H01L 21/768

(52) U.S. Cl. CPC H01L 23/535

(57) ABSTRACT

An interconnection structure includes a first interconnection layer and a second interconnection layer. The first interconnection layer includes a conductive feature extending through a first dielectric layer. The second interconnection layer includes a metal contact and at least one conductive structure extending through a second dielectric layer formed over the first interconnection layer. The metal contact is configured to overlay and interconnect with the conductive feature. A portion of the conductive feature closest to the conductive structure is recessed with a depth a from a top surface of the conductive feature.

### BACKGROUND

As the semiconductor industry introduces new generations of integrated circuits (IC) having higher performance and more functionality, the density of the elements forming the ICs increases, while the dimensions, sizes and spacing between components or elements are reduced. One of the hurdles to support the miniaturization device with increased number of circuits built on tighter space is the leakage induced by the thinner isolation spaced devices, for example, the leakage between the interconnect structure and the conductive contact of the diffusion regions.

Therefore, there is a need in the art to provide an improved device that can address the issues mentioned above.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-6 are cross-sectional side views of various stages of manufacturing an interconnect structure, in accordance with some embodiments.

FIGS. 7 and 8 are cross-sectional side views of various stages of manufacturing another interconnect structure, in accordance with some embodiments.

FIGS. 9-18 are cross-sectional side views of various stages of manufacturing a further interconnect structure, in accordance with some embodiments.

FIG. 19 is a flow chart of a method of manufacturing an interconnect structure in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The integrated circuit (IC) fabrication process can be divided into three stages, including a front end of the line (FEOL), middle of the line (MOL) or middle end of the line (MEOL), and back end of the line (BEOL). Each of the three stages may include some or all of operations, such as patterning (for example, photolithography and etching), implantation, metal and dielectric material deposition, wet or dry clean, and planarization such as etch back process or chemical mechanical planarization (CMP). In FEOL, various devices such as transistors are formed. The formation of transistors in the FEOL stage involves processes for forming source/drain (S/D) regions and gate structures of the transistors. In MEOL, low-level interconnects or contacts are formed to connect regions of the transistors, such as the S/D regions and gates to high level-interconnects formed in BEOL. The MEOL interconnects are embedded in a dielectric material or a stack of dielectric materials. In BEOL, multiple metallization layers (M₀ to Mₓ) are formed. Each of the metallization layers M₀ to Mₓ may include the high-level interconnects, for example, vias or metal wires or metal lines, embedded in one or more interlayer dielectric (ILD) layers. The high-level interconnects may have larger CD or linewidth and wider spaces between each other compared to those formed in MOEL.

To form the M₀ metallization layer, an etch stop layer (ESL) may be formed over a conductive contact VD embedded in a dielectric layer. The etch stop layer may be formed from material with a high selectivity in a subsequent wet clean process. A low-k dielectric layer is then formed on the ESL. Portions of the low-k dielectric layer are removed to form openings to expose ESL. A wet clean step is then performed to remove the ESL within the openings to expose the underlying VD. The openings are then filled with conductive material to form the M₀ contacts. At least one of the M₀ contacts may be designed to provide electric connection to the S/D region, gate region, or other diffusion regions of the devices formed in FEOL. Therefore, it is desired to have the M₀ contact formed over the underlying VD with a well-controlled overlay (OVL). When the overlay window shifts, the distance between the VD and the closest neighboring conductive structure designed to be isolated from the VD in the M₀ metallization layer is shortened. The shortened distance may cause or induce a leakage between the VD and the closest neighboring conductive structure, and thus degrades the device performance. The leakage worsens as the dimension of the M₀ pitches decreases.

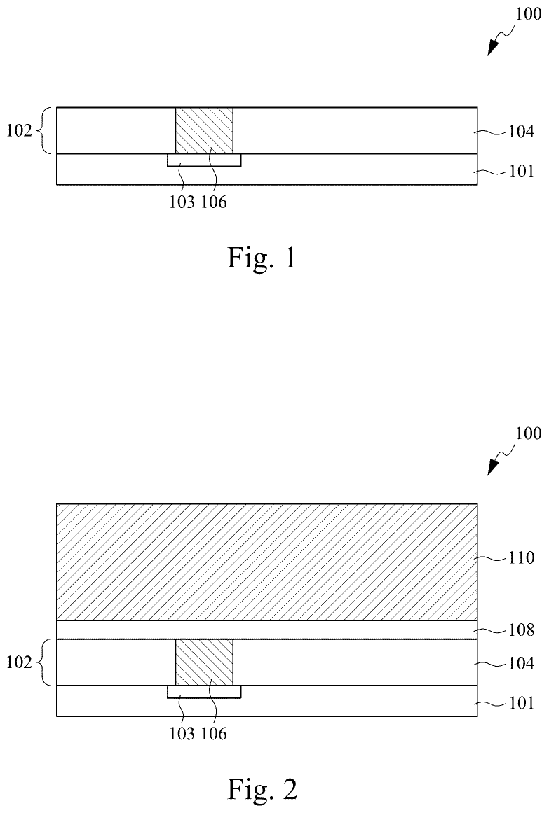

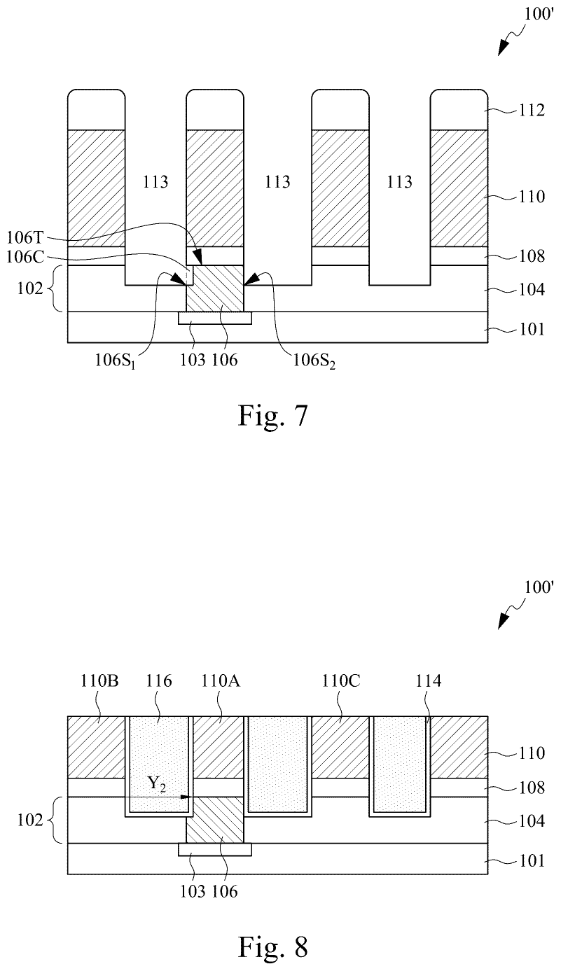

To minimize the leakage, an interconnect structure formed by a reversed patterning process is provided according to various embodiments of the present disclosure. FIGS. 1-6 are cross-sectional side views of various stages of manufacturing an interconnect structure 100 using a reversed patterning process in accordance with some embodiments. FIGS. 7-18 are cross-sectional side views of various modification of the interconnect structures according to some embodiments. The interconnect structure 100 may be formed on various devices of a semiconductor structure. For example, the interconnect structure 100 may include a low-level interconnect structure form in the MEOL stage over a substrate 101 in which one or more devices, such as transistors, diodes, imaging sensors, resistors, capacitors, inductors, memory cells, combinations thereof, and/or other suitable devices. In some embodiments, the interconnect structure 100 may be formed over the transistors, such as nanostructure FET having a plurality of channels wrapped around by a gate electrode layer. It will be appreciated that the interconnect structure 100 may be used in other fabrication stages and to interconnect various conductive structures in addition to those described with reference to FIGS. 1-18.

As shown in FIG. 1, the interconnection structure 100 formed on the substrate 101 includes an interconnection layer 102, which may be an interlayer dielectric (ILD) layer or an intermetal dielectric (IMD) layer. The interconnect layer 102 includes a dielectric layer 104 and one or more conductive features 106 (only one is shown) disposed in the dielectric layer 104. The dielectric layer 104 may include low-k dielectric material or any dielectric layer that may be used as an etch stop layer during subsequent trench and via patterning for metal contacts. The dielectric material may include but not limited to tetraethylorthosilicate oxide (TEOS), un-doped silicate glass, phosphosilicate glass (PSG), borophosphosilicate glass (BPSG), fused silica (FSG), boron doped silicon glass (BSG), SiN, SiOₓC_{y}, Spin-on-glass, spin-on-polymers, silicon carbon material, compounds thereof, composite thereof, or any suitable material formed by CVD, FCVD, PECVD, spin coating, or other suitable process.

The conductive feature 106 may include an electrically conductive material, such as Cu, Co, Ru, Mo, Cr, W, Mn, Rh, Ir, Ni, Pd, Pt, Ag, Au, Al, alloys thereof, or other suitable material. The conductive feature 106 may be formed by physical vapor deposition (PVD), CVD, ALD, or other suitable processes. The conductive features 106 may be electrically connected to conductive structure 103 formed in the substrate 101 under the interconnection structure 100. According to some embodiments, the conductive feature 106 may serve as a contact VD to interconnect the conductive structure 103, which may include a gate or a S/D region of a transistor or other devices formed in the substrate 101.

In FIG. 2, a metal layer 110 is formed over the interconnect layer 102. As the semiconductor device dimensions continue extreme shrinking to comply with the 3 nm node design rule, tungsten (W) that has been used for years as a MOL metal contact approaches critical limits. As a result, alternative metals such as Ru, Mo, Co, Ir, and other platinum group metals with low bulk resistivity (ρ) and short electron mean-free-path (λ) have been developed to form the metal contacts at small areas. These metallic materials do not require a diffusion barrier, such that the volume to form the interconnect can be maximized. Therefore, the metal layer 110 may be formed of Ru, Co, Mo, Ir, and other metals with similar characteristics in some embodiments. The metal layer 110 may be formed by CVD, PVD, or ALD.

Although Ru and other metal materials have been proven to be better candidates for forming the interconnects at small areas, it may be difficult to adhere Ru to the underlying dielectric layer. When a CMP process is required subsequently, Ru tends to peel from the underlying dielectric layer. Therefore, a liner layer 108 may be formed before the metal layer 110 is formed to enhance adhesion between the metal layer 110 and the dielectric layer 104.

The liner layer 108 may include TiN, AlOₓ, AlON, TaN, or other suitable materials to provide sufficient adhesion to the underlying dielectric 104. The liner layer 108 may have a thickness ranging from about 0 to 20 nm and may be formed by CVD, PVD, ALD, or other suitable processes. In some embodiments, before forming the liner layer 108, a pre-treatment process may be performed on the top surface of the dielectric layer 104 and the conductive feature 106 to clean the reaction surface for a better selectivity of the formation of the liner layer 108. The pre-treatment process may include solvent clean, acid clean or plasma clean.

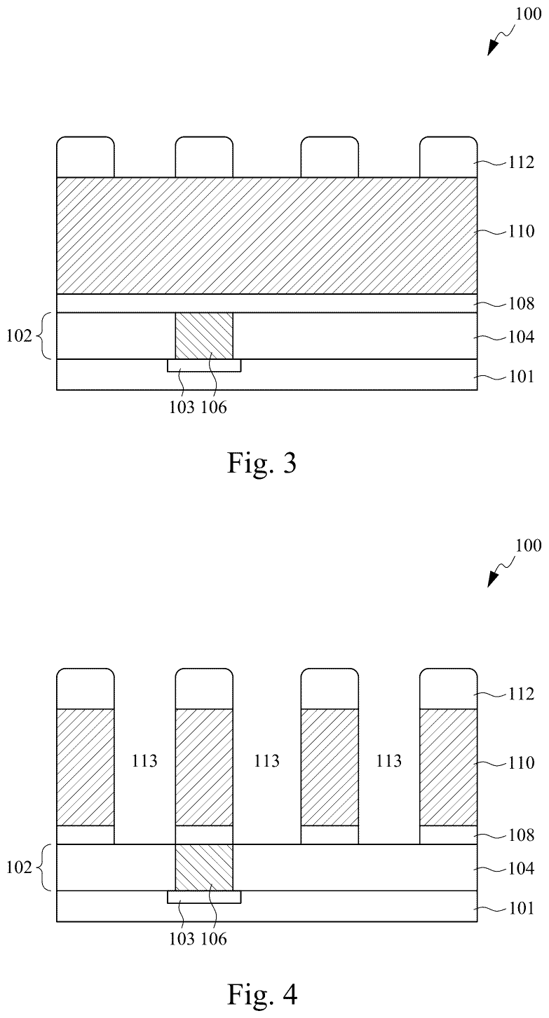

As shown in FIG. 3, a hard mask 112 is formed on the metal layer 110. The hard mask 112 may be formed by depositing a hard mask material such as SiN and a photolithography and etching process. The patterned hard mask 112 exposes portions of the metal layer 110. A portion of the hard mask 112 may cover the portion of the metal layer 110 directly above the conductive feature 106 for forming a metal contact of the conductive feature 106. In FIG. 4, the metal layer 110 exposed by the hard mask 112 and the underlying liner layer 108 are removed to form openings 113 that expose portions of the dielectric layer 104. According to some embodiments, the portions of the metal layer 110 and the liner layer 108 may be removed by an anisotropic etching process such as reactive ion etching (RIE) or other dry etching processes. The RIE process transfers the patterns of the hard mask 112 to the metal layer 110 and the liner layer 108 using plasma formed from one or more etching gases. The plasma is formed when a high electric field breaks down the gas molecules to ions, neutral and radicals. Typically, an electric field is directly applied to a substrate or wafer. The etching gas species are highly reactive and can etch materials in both chemical form and physical (sputtering) form. For example, when the metal layer 110 is formed of Ru, O₂ may be used in the plasma etch to form volatile solid RuO₃ and RuO₄ that melt near room temperature. In the situation that the undesired solid RuO₂ is formed during the plasma etching process, gas species such as N₂, Cl₂, CH₄, and CF₄ may be added to the O₂ plasma to enhance the removal of RuO₂. The etching rate of Ru may be adjusted by controlling the percentage of O₂ in the O₂ plasma. For example, the RIE process may use O₂/Ar and O₂/N₂ feed gas to control the etch rate. When Ar is added with O₂, the etch rate may decrease as the ratio of Ar/(Ar+O₂) increases. On the contrary, the addition of Cl₂ may improve the etching efficiency of Ru.

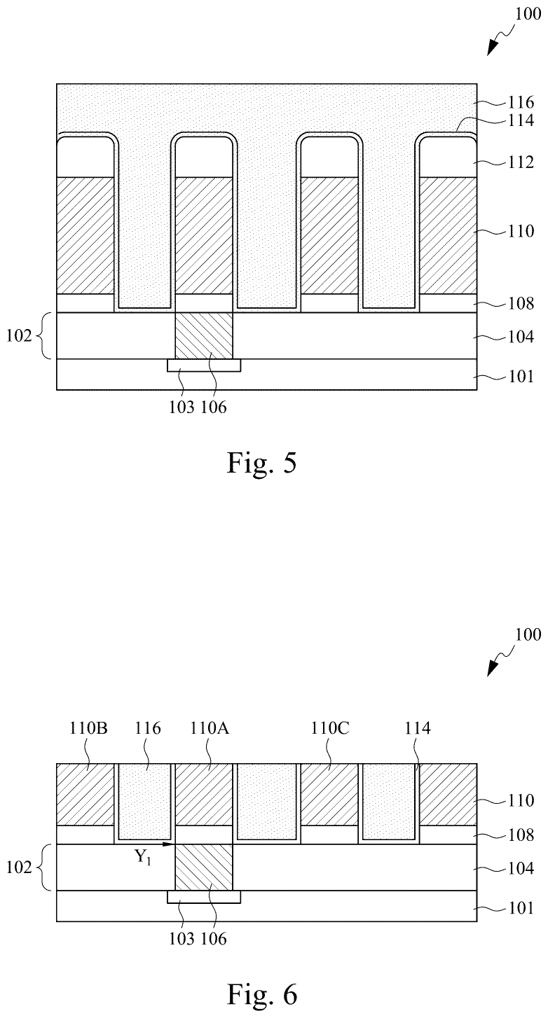

In FIG. 5, a liner layer 114 may be conformally formed on the exposed surfaces of the dielectric layer 104, the liner layer 108, the metal layer 110, and the hard mask 112. The liner layer 114 may be formed of SiOC by CVD or other suitable process and have a thickness ranging from about 3 nm to about 8 nm. Other materials such as SiN, SiCN, SiO, SiON or other suitable materials can also be used for forming the liner layer 114. In some embodiments, air gaps (not shown) may also be formed between the remaining metal layers 110 and the liner layer 114 to reduce the parasitic capacitance and to prevent leakage between neighboring conductive features or structures. A dielectric layer (ILD) 116 is then formed over the liner layer 114 and fills the openings 113. The dielectric layer 116 may be formed of low-k dielectric materials such high density plasma (HDP) oxide, TEOS, plasma-enhanced TEOS (PE-TEOS), O₃ TEOS, undoped Silicate Glass (USG), PSG, BSG, BPSG, fluorinated Silicate Glass (FSG), spin-on glass (SOG), a silazane (TOSZ), or any combination thereof, or may be formed from the foregoing or any combination thereof. In some embodiments, the dielectric layer 114 may include or be formed of silicon nitride, silicon oxynitride and/or other low-k materials.

A CMP process is then performed to planarize the interconnect structure 100. After the CMP process, the metal layer 110 has a height or thickness of about 20 nm to about 100 nm. As shown in FIG. 6, a portion of the remaining metal layer 110A directly above the conductive feature 106 serves as a metal contact to electrically connect the conductive feature 106 with higher-level interconnects and/or external devices. Other remaining portions of the metal layers 110, including two immediate neighboring portions 110B and 110C may include conductive structures such as metal lines or wires extending horizontally through the dielectric layer 116, and vias to connect other conductive structures formed in the interconnect layer 102. To maintain satisfying device performance, the conductive feature 106 needs to be properly isolated from the conductive structures, particularly the conductive structures 110B and 110C closest to the conductive feature 106.

As discussed above, as the device dimension continuously shrinks, leakage between the conductive feature and conductive structures designed to be isolated from the conductive feature is likely to happen, particularly when an OVL window shifts. For example, when the conductive feature and its overlaying contact are not properly aligned with each other, the distance between the conductive feature and the neighboring conductive structure at the same level of the overlaying contact is shortened. The shortened distance may result in a shortened leakage path and thus cause or induce leakage between the conductive feature and the neighboring conductive structure. In the embodiment as shown in FIG. 6, the leakage path Y₁ may be measured by the distance from the proximal bottom corner of the liner layer 108 under the conductive structure 110B to the proximal upper corner of the conductive feature 106.

One way to prevent the leakage includes extending or lengthening the leakage path. FIGS. 7 and 8 show an embodiment to extend or lengthen the leakage path according to some embodiments. The process as shown in FIG. 7 starts from the process as shown in FIG. 3. In FIG. 7, an RIE process is performed to remove the metal layer 110 uncovered by the hard mask 112. In contrast with FIG. 4, the RIE process does not stop while the dielectric layer 104 is exposed. In FIG. 7, the RIE process continues until a portion of the conductive feature 106 as well as a portion of the dielectric layer 104 are removed. The removed portion (106C) results in a chamfered top corner of the conductive feature 106. The removed portion 106C as shown in FIG. 7 has a substantially rectangular shape, such that the chamfered top corner has a flat surface profile. The flat surface of the chamfered top corner is recessed from a main top surface 106T of the conductive feature 106. The top surface levels of two opposite sidewalls 106S₁ and 106S₂ of the conductive feature 106 are not coplanar. The shortest distance between the immediate adjacent conductive structure 110B and the conductive feature 106 is thus increased by the thickness of the removed portion at the sidewall S₁. The processes as shown in FIGS. 5 and 6 are then performed to form the interconnect structure 100′ as shown in FIG. 8. In FIG. 8, the leakage path Y₂, that is, the shortest distance, between the conductive feature 110B and the conductive feature 106 is extended from Y₁ to Y₂, where Y₂>Y₁. With the longer leakage path, the leakage between the conductive feature 110B and the conductive feature 106 can be effectively reduced or prevented. In some embodiments, the removed portion 106C may have a shape different from the rectangular shape to result in a different surface profile at the chamfered top corner. For example, as shown in FIG. 11, the chamfered top corner has a curved surface profile.

After the interconnect structure 100′ is formed, multiple metallization layers (not shown) may be formed in the BEOL stage. Each of the metallization layers may include metal lines extending horizontally through a dielectric layer. Vias may be formed to interconnect the metal contact 110A and other conductive structures formed from the metal layer 110 in a vertical direction. The metallization layers are then encapsulated by an ILD layer with contact pads formed thereon to electrically connect external devices. After the BEOL stage, the post-fab processes, including wafer testing, die separation, die testing, IC packaging, and final device testing are performed.

A portion of the conductive feature 106 may be removed without significantly damaging the surrounding structures by controlling the etching selectivity of the metal layer 110 with respect to the conductive feature 106 in the RIE process. For example, as the etching rates of the metal layer 110 and the conductive feature 106 may depend on the percentages or concentrations of the etching species used to remove the metal layer 110 and the conductive feature 106, respectively, the etching selectivity of the metal layer 110 may be reduced by reducing percentage of the etching species used to remove the metal layer 110. Alternatively, the etching selectivity of the metal layer 110 may be reduced by increasing the percentage of the etching species used to remove the conductive feature 106. In some embodiments where tungsten (W) is used for forming the conductive feature 106, the RIE ion etching rate of W may be determined as a function of oxygen concentration or percentage. For example, when the etching species used in the RIE process includes Cl₂, O₂, CH₄, and N₂, the percentage of O₂ may be reduced to allow a portion of the W conductive feature 106 to be removed by the RIE process.

The percentage of O₂ may be controlled at a level where both the metal layer 110 and the conductive feature 106 can be etched from the beginning of etching the metal layer 110. That is, the etching selectivity of the metal layer 110 to the conductive feature 106 may be controlled at approximately the same level throughout the RIE process. According to some embodiments, the one-step RIE etching process may be performed with a percentage of O₂ of about 20% to about 90%, Cl₂ of about 20% to about 50%, and fluorine-containing (F₂-based) gas of about 5% to about 30%. The selectivity of Ru to SiN may be controlled at about 2.4 to 24, and the selectivity of Ru to W may be controlled at about 2.4 to about 36.

Alternatively, the percentage of O₂ may be adjusted at a first level where the etching selectivity of the metal layer 110 is higher, and then reduced to a second level where the etching selectivity of the conductive feature is higher when approaching the conductive layer 106, for example, when the metal layer 110 is removed to expose the liner layer 108 is exposed. In yet another embodiment, the percentage of O₂ may be gradually reduced when approaching the conductive feature 106. For example, the first level of the selectivity of Ru to W may be controlled at or larger than 24, and the selectivity of Ru to SiN may range from about 2.4 to about 24. In the second level of the selectivity of Ru to W may be controlled between 2.4 to about 36. According to some embodiments, the first level of the selectivity of Ru to W may be achieved by adding O₂ with a percentage of about 20% to about 90% and Cl₂ with a percentage of about 20% to about 50% without introducing F₂-based gas. The second level of the selectivity of Ru to W may be achieved by adding O₂ with a percentage of about 20% to about 60%, Cl₂ with a percentage of about 20% to about 70%, and F₂-based gas with a percentage of about 5% to about 30%.

In some other embodiments, NF₃, CF₄, SF₆, CBrF₃, CHF₃, or other suitable fluorine-containing gas, or chlorine-or bromine-contained material containing fluorine, may be introduced in the O₂ plasma to convert a portion of W conductive feature 106 into volatile WF₆. As a result, by the RIE process, a portion of W conductive feature is removed. However, the O₂ may need to be maintained above a certain percentage to avoid an excessive amount of the W to be removed. Other parameters that may influence the etching rates of the metal layer 110 and the conductive features include the pressure, power, bias, and temperature of the RIE process. In some embodiments, the RIE process may be performed with a pressure of about 3 mT to about 100 mT, a power of about 150 W to about 2900 W, a bias of about 20 Wb/esc to about 1500 Wb/esc, and a temperature of about 0° C. to about 110° C. In the one-step RIE etching process, the temperature may range from as low as −20 C. to about 100° C. according to some embodiments. The fluorine-containing gas may be added at the beginning of the RIE process with a fixed percentage or a gradually increased percentage as the RIE process continues. Alternatively, the fluorine-containing gas may start to be introduced when the majority of the metal layer 110 is removed. The introduction of the fluorine-containing gas may be introduced with a fixed percentage or a gradually increased percentage.

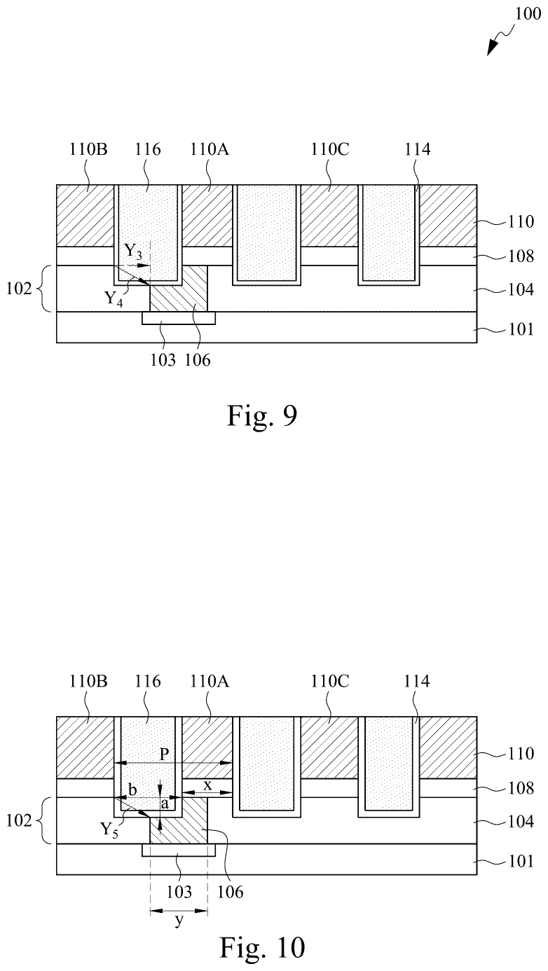

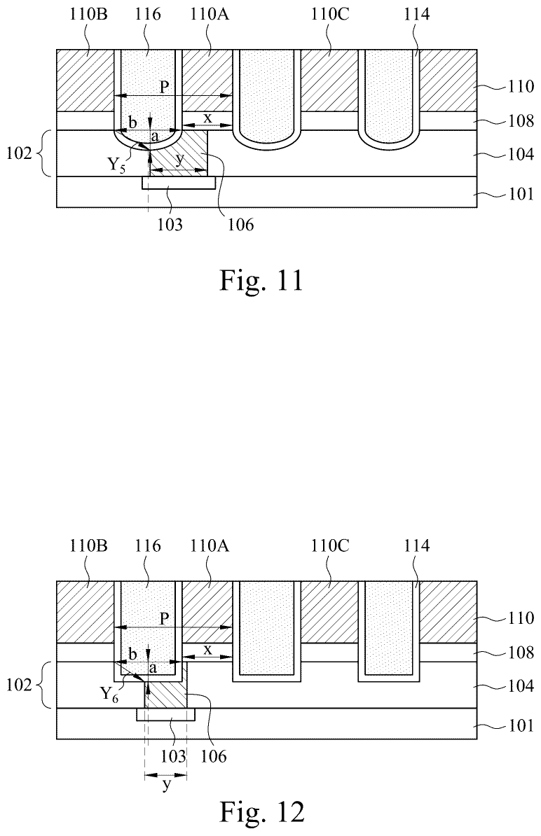

The embodiment as shown in FIGS. 1-8 shows the interconnect structure 100 with a well-controlled overlay (OVL). That is, the metal contact 110A is well aligned with the underlying conductive feature 106. When the metal contact 110A is formed with a poorly-controlled OVL, the leakage path may be significantly shortened and cause or increase leakage between the conductive feature 106 and the neighboring conductive structures 110B or 110C extending horizontally or vertically through the dielectric layer 116. FIGS. 9-18 are cross-sectional views showing various embodiments to enlarge M0/VD leakage window by lowering the etch selectivity of the metal layer 110 to the conductive feature, for example, selectivity of Ru/TiN to W. In FIGS. 9-18, the leakage path Y (Y₃-Y₇) is defined as the shortest distance between the closest conductive structure 110B (M0) and the conductive feature (VD). For example, in FIG. 9, Y₃ and Y₄ are measured from the lowest point of the conductive structure 110B to the closest point of the conductive feature 106. The same applies to the embodiments as shown in FIG. 10-18. FIG. 9 shows an embodiment where the leakage path shortened by the poorly-controlled OVL is extended by removing a portion of the conductive layer 106 in the RIE process. As shown in the figure, the portion of the conductive feature 106 as well as a portion of the dielectric layer 104 are removed to result in a recessed surface under the dielectric layer 116. The leakage path extends from Y₃ to Y₄, where Y₄>Y₃. The extended leakage path may thus suppress or minimize the leakage between the conductive feature 106 and the conductive structure 110B which is designed to be isolated from the conductive feature 106.

The dimensions and geometry of the portion of the conductive feature 106 to be removed may depend on the dimensions and relative location of the conductive feature 106 with respect to the metal contact 110A. For example, when the width of the conductive feature 106 is larger than that of the metal contact 110A, a portion of the conductive feature 106 may extend beyond the metal contact 110A laterally. As a result, the leakage path to the neighboring conductive structure 110B or 110C is shortened, which increase the possibility of leakage even when the conductive layer 106 is well aligned under the metal contact 110A. Therefore, the dimensions and geometry of the removed portion of the conductive feature 106 may be different from the removed portion of the conductive feature when the width of the conductive feature 106 is about the same or smaller than the metal contact 110A formed thereon. FIGS. 10-18 show the embodiments of the interconnect structures with various dimensions and geometries.

FIG. 10 shows a first embodiment in which the width “y” of the conductive layer 106 is smaller than or equals to the width “x” of the metal contact 110A over the conductive layer 106. That is, y≤x in the first embodiment. After the RIE process, the remaining metal layer 110, including the metal contact 110A, the neighboring conductive structures 110B and 110C and other conductive structures, has a thickness of about 20 nm to about 100 nm after CMP process. The pitch P of the metal contact 110A is about 12 nm to about 30 nm. The liner layer has a thickness of about 0 nm to about 20 nm. The bottom critical dimension (BCD) “b” of the dielectric layer 116 between the metal contact 110A and the conductive structure 110B is about 5 nm to about 14 nm. The removed portion of the conductive feature 106 results in a recess with a depth “a” ranging from about 0.5 nm to about 10 nm. The ratio a/b may range from about 0.1 to about 1. The recess formed by the removed portion of the conductive layer 106 has a substantially rectangular shape, and the leakage path Y₅ is longer than the leakage path without the removed portion of the conductive feature 106.

FIG. 11 shows a second embodiment when y≤x. In the second embodiment, the thickness or height of the metal layer 110, liner layer 108, and ILD layer 116 and the pitch P are substantially the same as those in the first embodiment shown in FIG. 10. The ranges of the BCD “b” of the dielectric layer 116 and the recessed depth may also be substantially the same as those in the first embodiment. However, the depth of the removed portion of the conductive layer 106 gradually varies towards the conductive structure 110B to result in a recessed surface. In some embodiments, the recessed surface may have curved profile. When the maximum removed depth “a” is the same as that in the first embodiment with rectangular removed portion of the conductive feature 106, the same leakage path Y₅ can be achieved while less amount of the conductive feature 106 needs to be removed.

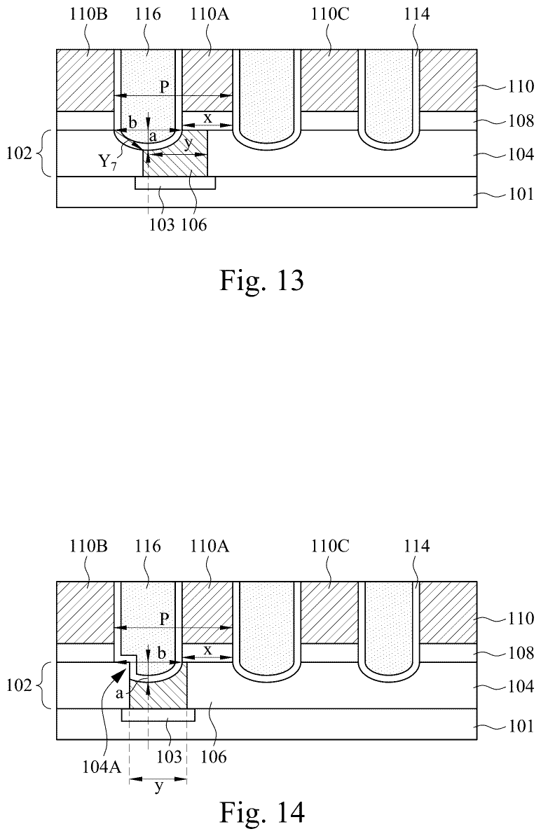

FIGS. 12 and 13 show a third and a fourth embodiments when y≤x. In the third and fourth embodiments, the thickness of the metal layer 110, liner layer 108, and ILD layer 116 and the pitch P are substantially the same as those in the first and second embodiments. The ranges of the ILD BCD “b” and the recessed depth are also substantially the same as those in the first embodiment. However, poor alignment between the conductive feature 106 and the metal contact 110A worsens in the third and fourth embodiments. That is, the location of the conductive feature 106 shifts further towards the conductive structure 110B in the third and fourth embodiments. In FIG. 12, the shortened leakage path Y₆ is shortened compared to the leakage path Y₅ as shown in FIG. 11. In FIG. 13, as the conductive feature 106 extends laterally over the lowest point of the curved recessed surface, the shortest distance between the proximal bottom corner of the conductive feature 110B and the closest top corner of the conductive feature 106 is further shortened compared to that in the third embodiment as shown in FIG. 12. As a result, the leakage path Y₇ is shorter than Y₆. Therefore, although less amount of the conductive feature 106 needs to be removed, when the leakage path may be shorter than desired with the curved profile when the conductive feature 106 extends further towards the conductive structure 110B.

FIG. 14 shows a fifth embodiment when y≤x. In the fifth embodiment, the thickness of the metal layer 110, liner layer 108, and ILD layer 116 and the pitch P are substantially the same as those in the third and fourth embodiments as shown in FIGS. 12 and 13. The ranges of the ILD BCD “b” and the recessed depth are also substantially the same as those in the first embodiment. Similar to those as shown in FIGS. 11 and 13, the removal depth of the conductive feature 106 gradually varies to result in a curved recessed surface. The RIE process is configured to remove a portion of the conductive feature 106 without removing the dielectric layer 104. As a result, a stepped portion 114A is formed along the leakage path between the conductive feature 106 and the conductive structure 110B. According to some embodiments, the stepped portion 104A may be formed by adjusting the etching selectivity during the RIE process as shown in FIG. 7. For example, the RIE process may be performed with a lower etching selectivity to the dielectric layer 114 with respect to the conductive feature 106.

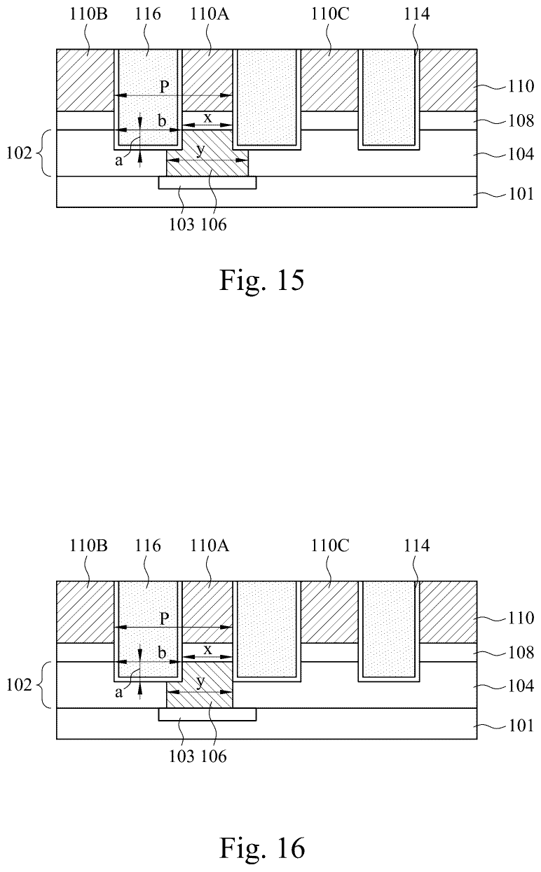

FIG. 15 shows a first embodiment of the interconnect structure when y>x. The metal layer 110 may have a height or depth of about 20 nm to about 100 nm after performing the CMP process as described with reference to FIG. 6. The liner layer 108 between the metal contact 110A and the underlying dielectric layer 104 may have a thickness of about 0 nm to about 20 nm. The pitch P of the conductive contact 110A may range from about 12 nm to about 30 nm. In the first embodiment with y>x, both sidewalls of the conductive feature 106 extend laterally beyond the corresponding sidewalls of the metal contact 110A disposed directly above. A portion of the conductive feature 106 at each lateral side is removed with a depth “a” by the RIE process. As a result, both sidewalls are recessed from the middle portion by “a” which may range from about 0.5 nm to about 10 nm. The bottom critical dimension “b” may range from about 5 nm to about 14 nm. The ratio of a/b may range from about 0.1 to about 1. The leakage paths from both neighboring conductive structure 110B and 110C are thus increased to minimize the leakage to the conductive feature 106.

FIG. 16 shows a second embodiment of the interconnect structure when y>x. In the second embodiment with y>x, the conductive feature 106 has one sidewall aligned with the corresponding sidewall of the metal contact 110A disposed directly thereon, and the other sidewall extending laterally beyond the opposing sidewall of the metal contact 110A. The thickness (height) of the metal layer 110, liner layer 108, and ILD layer 116 and the pitch P may be substantially the same as those in the first and second embodiments. The ranges of the ILD BCD “b” and the recessed depth are also substantially the same as those in the first embodiment with y>x as shown in FIG. 15. However, only the side of the conductive feature 106 extending over its corresponding sidewall of the metal contact 110A has a recessed portion formed by the RIE process. The recessed depth results in a longer leakage path, and thus the leakage may be properly controlled.

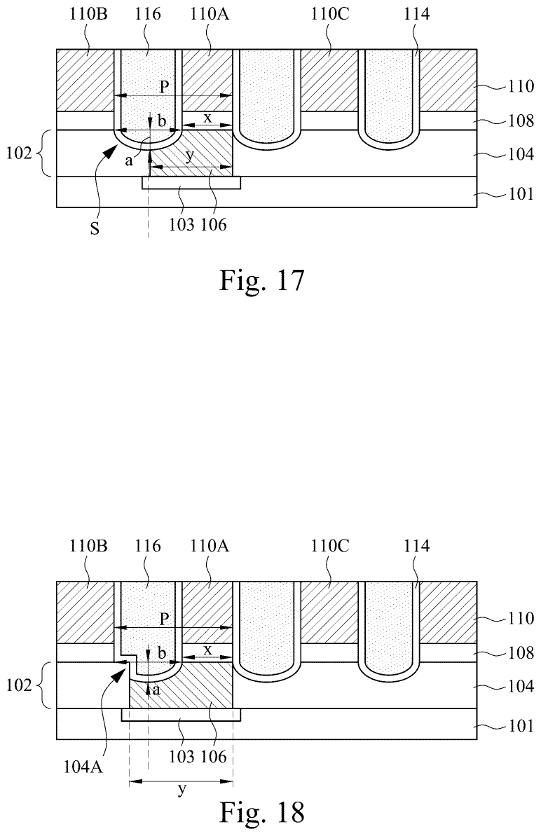

FIG. 17 shows a third embodiment of the interconnect structure when y>x. In the third embodiment with y>x, the conductive feature 106 has one sidewall aligned with the corresponding sidewall of the metal contact 110A disposed directly thereon, and the opposing sidewall extending laterally beyond the other sidewall of the metal contact 110A. The thickness of the metal layer 110, liner layer 108, and ILD layer 116 and the pitch P are substantially the same as those in the first and second embodiments. The ranges of the ILD BCD “b” and the recessed depth are also substantially the same as those in the first embodiment as shown in FIG. 16. However, only the side of the conductive feature 106 extending over its corresponding sidewall of the metal contact 110A has a recessed portion formed by the RIE process. In FIG. 17, the depth of the conductive feature 106 removed by the RIE process is gradually changing from the sidewall of the metal contact 110A towards the conductive feature 110B. As a result, a reduced amount of the conductive feature 106 needs to be removed to achieve the same leakage path. However, as discussed with reference to FIG. 13, the leakage path may be shortened with the curved recessed surface when the conductive feature 106 extends laterally over the lowest point of the curved recessed surface. Although it is not shown in the drawings, when the conductive feature 106 extends laterally beyond the other sidewall of the metal contact 110A towards the conductive structure 110C, the same process may be applied to form a curved recessed surface of the extended portion towards the conductive structure 110C.

FIG. 18 shows a fourth embodiment of the interconnect structure when y>x. In the fourth embodiment with y>x, one side of the conductive feature 106 is aligned with the corresponding sidewall of the metal contact 110A disposed directly thereon, and the other sidewall extending laterally beyond the other sidewall of the metal contact 110A towards the conductive structure 110B. The thickness of the metal layer 110, liner layer 108, and ILD layer 112 and the pitch P are substantially the same as those shown in FIGS. 15-17. The ranges of the ILD BCD “b” and the recessed depth are also substantially the same as those shown in FIGS. 15-17. However, only the side of the conductive feature 106 extending over its corresponding sidewall of the metal contact 110A has a recessed portion formed by the RIE process. In FIG. 18, the depth of the conductive feature 106 removed by the RIE process is gradually changing from the sidewall of the metal contact 110A towards the conductive structure 110B. As a result, a reduced amount of the conductive feature 106 needs to be removed to achieve the same leakage path. However, as discussed with reference to FIG. 13, the leakage path may be shortened with the curved recessed surface when the conductive feature 106 extends laterally over the lowest point of the curved recessed surface. Although it is not shown in the drawings, when the conductive feature 106 extends laterally beyond the other sidewall of the conductive contact 110A towards the conductive structure 110C, the same process may be applied to form a curved recessed surface of the extended portion towards the conductive structure 110C. The structure as shown in FIG. 18 shows a modification with the conductive feature 106 extending laterally over the lowest point of the curved recessed surface. In FIG. 18, the RIE process is controlled to remove the conductive feature 106 without removing the dielectric 104 layer. Similar to the structure as shown in FIG. 14, a stepped portion 114A is formed along the leakage path between the neighboring conductive structure 110B and the conductive feature 106.

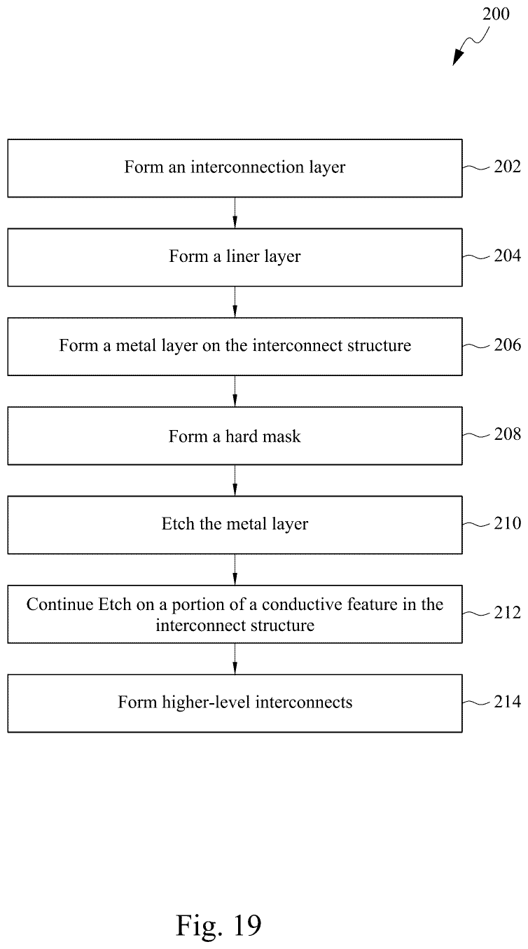

FIG. 19 is a flow chart of a method 200 of manufacturing the interconnect structure 100 in accordance with some embodiments. It is noted that the operations of the method 200, including any descriptions given with reference to the figures, are merely exemplary and are not intended to be limiting beyond what is specifically recited in the claims that follow. Additional operations may be implemented before, during, and after the method 200, and some operations may be replaced, eliminated, or rearranged in any desired order in accordance with various embodiments of the method 700.

The method 200 starts at operation 202 by forming an interconnection layer over a substrate. The interconnection layer may be the interconnection layer 102 as previously described with reference to FIG. 1. The interconnection layer 102 may include the conductive feature 106 in the dielectric layer 104. The conductive feature 106 may include a contact VD or a contact MD for connecting a S/D region, a gate region, or other diffusion region 103 of a transistor formed in a substrate 101.

At operation 204, a liner layer is formed on the interconnection layer. A metal layer is then formed on the liner layer at operation 206. The liner layer may be the liner layer 108 and the metal layer may be the metal layer 110 formed by the processes discussed above with respect to FIG. 2. In some embodiments, the liner layer 108 is made of materials that provides enhanced adhesion of the metal layer to the dielectric layer 104. For example, the liner layer 108 may be a TiN when Ru is used for forming the metal layer 110. Other materials such as AlOₓ, AlON, and TaN may also be used for forming the liner layer 108. The metal layer 110 may be formed of Ru, Co, Mo, Ir, other platinum group metal, or other materials with bulk resistivity with a small area.

At operation 208, a hard mask layer is formed on the metal layer 110. The hard mask layer may be the hard mask layer 112. The hard mask layer may be formed by the processes discussed above with respect to FIG. 3. In some embodiments, the hard mask layer may be a silicon nitride (SiN) layer.

At operation 210, the metal layer is etched to form individual metal contact or other conductive structures, such as the metal contact 110A and the conductive structures 110B and 110C. In some embodiment, the metal layer 110 may be etched by a RIE process with etching species to remove metal layer by converting the materials of the metal layer into volatile substances or compounds that melt in room temperature. For example, when the metal layer is formed of Ru, O₂ plasma is used for etching the metal layer 110.

At operation 212, the etching process continues to remove a portion of the conductive feature of the interconnection layer. The etched conductive feature may be referred to any of the conductive feature 106 as shown in any of FIGS. 8-28. The etching processes at operations 210 and 212 may use the same etching species with the same etch selectivity of the metal layer 110 with respect to the conductive feature 106. Alternatively, a higher etching selectivity of the metal layer 110 may be higher at operation 212 compared to that for etching the conductive feature 106 of at operation 212. After operation 212, the conductive feature 106 may have a recessed portion, such that a leakage path between the conductive feature 106 and a conductive structure made of the metal line 110 closest to the conductive feature 106 may be lengthened.

At operation 212, a portion of the dielectric layer, for example, the dielectric layer 104 adjacent to the conductive feature 106 may also be removed to result in a surface level with the recessed surface of the conductive feature 106. The recessed surface may be flat or curved according to some embodiments. In some embodiments, the RIE process does not remove the dielectric layer 104 while removing the conductive feature 106 to create a stepped portion along the leakage path. The stepped portion may be formed by adjusting the etching selectivity of the dielectric layer 104 with respect to the conductive feature 106.

At operation 214, multiple metallization layers each including higher-level interconnects may be formed, followed by formation of contact pads, post-fab testing and packaging.

Method 200 prevents or minimizes potential leakage between a conductive structure (e.g., a lowest metal layer (M0) in an interconnection structure) and an underlying conductive feature (e.g., VD). The conductive structure is formed during the process of forming a metal contact to interconnect the underlying conductive feature. In method 200, a reversed patterning process is used for forming the metal contact and the conductive structure over the conductive feature. That is, the metal layer is formed and patterned, and the interlayer dielectric layer is deposited between and over the patterned metal layer. In the process of patterning the metal layer, a portion of the underlying conductive feature is removed to increase the shortest distance between the conductive structure and the conductive feature. As a result, the leakage path is increased to reduce or prevent the leakage from the conductive structure to be isolated from the underlying conductive feature.

According to one embodiment, an interconnection structure is provided. The interconnection structure includes a first interconnection layer and a second interconnection layer. The first interconnection layer includes a conductive feature extending through a first dielectric layer. The second interconnection layer includes a metal contact and at least one conductive structure extending through a second dielectric layer formed over the first interconnection layer. The metal contact is configured to overlay and interconnect with the conductive feature. A portion of the conductive feature closest to the conductive structure is recessed with a depth a from a top surface of the conductive feature.

In another embodiment, an interconnection structure is provided. The interconnection structure includes a conductive feature extending through a first dielectric layer and a metal contact overlaying and interconnect with the first interconnection layer. At least one side of the conductive feature has a top corner recessed with a depth from a top surface of the conductive feature.

In yet another embodiment, a method is provided. The method includes providing an interconnection layer including a conductive feature extending through a first dielectric layer, forming a metal layer on the interconnection layer, and etching portions of the metal layer to form a plurality of openings, and continuing the etching to remove a portion of the conductive feature exposed within one of the openings. The openings are then filled with a second dielectric layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. An interconnection structure, comprising:
a first interconnection layer comprising a conductive feature extending through a first dielectric layer; and
a second interconnection layer comprising a metal contact and at least one conductive structure extending through a second dielectric layer formed over the first interconnection layer, wherein the metal contact is disposed to overlay and interconnect with the conductive feature, and wherein
a portion of the conductive feature closest to the conductive structure has a top surface lower than a top surface of a remaining portion of the conductive feature.

2. The interconnection structure of claim 1, wherein a height difference a between the top surfaces of the portion and the remaining portion of the conductive feature is about 5 nm to about 10 nm.

3. The interconnection structure of claim 1, wherein a/b is about 0.1 to about 1, where b is a bottom critical dimension of the second dielectric layer between the conductive structure and the metal contact.

4. The interconnect structure of claim 1, wherein the portion of the conductive feature has a flat top surface.

5. The interconnect structure of claim 1, wherein a portion of the first dielectric layer extending between the conductive structure and the conductive feature has a flat surface level with the top surface of the portion of the conductive feature.

6. The interconnection structure of claim 1, wherein the portion of the conductive feature closest to the conductive structure has a curved top surface and a height difference a between the top surfaces of the portion and the remaining portion of the conductive feature gradually increases towards between the top surfaces of the portion and the remaining portion of the conductive structure.

7. The interconnection structure of claim 6, wherein the first dielectric layer includes a step structure between the conductive structure and the conductive feature, and a top surface of the step structure is level with the top surface of the remaining portion of the conductive feature.

8. The interconnection structure of claim 1, wherein the top surface of the portion of the conductive feature is curved with a gradually varying depth.

9. The interconnection structure of claim 8, wherein a top surface of the first dielectric layer between the conductive structure and the recessed portion is level with the top surface of the remaining portion of the conductive feature.

10. The interconnection structure of claim 1, further comprising a liner layer interfacing the second dielectric layer with the metal contact, the conductive structure, the conductive feature, and the first dielectric layer.

11. An interconnection structure, comprising:
a conductive feature extending through a first dielectric layer; and
a metal contact overlaying and to interconnect with the conductive feature, wherein
at least one side of the conductive feature has a chamfered top corner such that a sidewall of the conductive feature is lower than a top surface of the conductive feature with a depth.

12. The interconnection structure of claim 11, wherein the chamfered top corner has a flat top surface lower than the top surface of the conductive feature.

13. The interconnection structure of claim 11, wherein the chamfered top portion has a curved top surface with a gradually increased depth from the top surface of the conductive feature.

14. A method, comprising:
providing an interconnection layer comprising a conductive feature extending through a first dielectric layer;
forming a metal layer on the interconnection layer;
etching portions of the metal layer to form a plurality of openings, and continuing the etching to remove a portion of the conductive feature exposed within one of the openings; and
filling the openings with a second dielectric layer.

15. The method of claim 14, further comprising forming a liner layer before forming the metal layer.

16. The method of claim 14, further comprising adjusting an etching selectivity of the metal layer to etch both the metal layer and the conductivity feature.

17. The method of claim 14, further comprising performing a reactive ion etching process with predetermined percentages of a first etching species to remove the metal layer and a second etching species to remove the conductive feature.

18. The method of claim 17, wherein a percentage of the first etching species is reduced while the etching continues to etch the conductive feature.

19. The method of claim 14, further comprising performing a reaction ion etching process with a first etching species to remove the metal layer and adding a second etching species when the etching continues to remove the conductive feature.

20. The method of claim 14, further comprising etching the metal layer to form a metal contact overlaying and interconnect with the conductive feature and at least one conductive structure to be isolated from the conductive feature.
